(19) United States
(12) Patent Application Publication
(10) Pub. No.: US 2026/0019321 A1
(43) Pub. Date: Jan. 15, 2026

(54) NON-UNIFORM DISCRETE ENVELOPE TRACKING

(71) Applicant: Samsung Electronics Co., Ltd., Suwon-si (KR)

(72) Inventors: Chance Anthony Tarver, Arlington, TX (US); Masoud Shahshahani, Allen, TX (US); Navneet Sharma, Allen, TX (US); Won Suk Choi, McKinney, TX (US); Gang Xu, Allen, TX (US)

(21) Appl. No.: 19/084,740

(22) Filed: Mar. 19, 2025

Related U.S. Application Data
(60) Provisional application No. 63/670,706, filed on Jul. 12, 2024.

(51) Int. Cl. H04L 27/36; H03F 3/24

(52) U.S. Cl. CPC H04L 27/36; H03F 3/24; H03F 2200/102; H03F 2200/451

(57) ABSTRACT

Methods and systems for non-uniform discrete envelope tracking. A method includes receiving one or more baseband signals and setting a plurality of initial non-uniform voltage levels. Each of the voltage levels in the plurality of non-uniform voltage levels is non-uniformly spaced from other voltage levels in the plurality of non-uniform voltage levels. The method further includes applying the plurality of initial non-uniform voltage levels to a power amplifier and changing one or more voltage values of the plurality of initial non-uniform voltage levels to generate a plurality of updated non-uniform voltage levels based on the one or more baseband signals.

### CROSS-REFERENCE TO RELATED APPLICATIONS AND CLAIM OF PRIORITY

The present application claims priority to U.S. Provisional Patent Application No. 63/670,706, filed on Jul. 12, 2024. The contents of the above-identified patent documents are incorporated herein by reference.

### TECHNICAL FIELD

The present disclosure relates generally to wireless communication systems. more specifically, the present disclosure relates to a system and method for non-uniform discrete envelope tracking.

### BACKGROUND

In 6G extreme-MIMO systems, there are likely to be hundreds of power amplifiers in a single base station. These power amplifiers typically consume the majority of the power budget of the base station. Moreover, their power-added efficiency (PAE), the main performance metric of a power amplifier, is often as low as 20%. The lower PAE is indicative of wasted power that contributes significantly to thermal concerns and increases the operational expenditure costs of a system. Additionally, the PAE tends to be lower for higher RF frequencies, further exacerbating the challenge for 6G design where Frequency Range 3 upper mid-band is being considered.

Accordingly, there is a need for systems and methods for improved envelope tracking systems that overcome these challenges.

### SUMMARY

The present disclosure relates generally to wireless communication systems and, more specifically, the present disclosure relates to a system and method for non-uniform discrete envelope tracking.

In one embodiment, a method is provided. The method includes receiving one or more baseband signals and setting a plurality of initial non-uniform voltage levels. Each of the voltage levels in the plurality of non-uniform voltage levels is non-uniformly spaced from other voltage levels in the plurality of non-uniform voltage levels. The method further includes applying the plurality of initial non-uniform voltage levels to a power amplifier and changing one or more voltage values of the plurality of initial non-uniform voltage levels to generate a plurality of updated non-uniform voltage levels based on the one or more baseband signals.

In another embodiment, an electronic device is provided. The electronic device includes a transceiver, and a processor operably coupled to the transceiver. The processor is configured to cause the electronic device to receive one or more baseband signals and set a plurality of initial non-uniform voltage levels. Each of the voltage levels in the plurality of non-uniform voltage levels is non-uniformly spaced from other voltage levels in the plurality of non-uniform voltage levels. The processor is further configured to cause the electronic device to apply the plurality of initial non-uniform voltage levels to a power amplifier and change one or more voltage values of the plurality of initial non-uniform voltage levels to generate a plurality of updated non-uniform voltage levels based on the one or more baseband signals.

In yet another embodiment, a non-transitory computer-readable medium is provided. The non-transitory computer-readable medium includes program code, that when executed by at least one processor of an electronic device, causes the electronic device to receive one or more baseband signals and set a plurality of initial non-uniform voltage levels. Each of the voltage levels in the plurality of non-uniform voltage levels is non-uniformly spaced from other voltage levels in the plurality of non-uniform voltage levels. The non-transitory computer-readable medium further includes program code, that when executed by at least one processor of an electronic device, causes the electronic device to apply the plurality of initial non-uniform voltage levels to a power amplifier and change one or more voltage values of the plurality of initial non-uniform voltage levels to generate a plurality of updated non-uniform voltage levels based on the one or more baseband signals.

Other technical features may be readily apparent to one skilled in the art from the following figures, descriptions, and claims.

Before undertaking the DETAILED DESCRIPTION below, it may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” means any device, system, or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for other certain words and phrases are provided throughout this patent document. Those of ordinary skill in the art should understand that in many if not most instances, such definitions apply to prior as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an example wireless network according to embodiments of the present disclosure;

FIG. 2 illustrates an example gNB according to embodiments of the present disclosure;

FIG. 3 illustrates an example UE according to embodiments of the present disclosure;

FIG. 4 illustrates an example signal envelope of a power amplifier;

FIG. 5A illustrates an example non-uniform discrete envelope tracking system according to embodiments of the present disclosure;

FIG. 5B illustrates an example flow chart of a discrete envelope tracking level calculator of the non-uniform discrete envelope tracking system of FIG. 5A according to embodiments of the present disclosure;

FIG. 6 illustrates an example method for non-uniform discrete envelope tracking according to embodiments of the present disclosure;

FIG. 7 illustrates an example signal envelope of a non-uniform discrete envelope tracking system according to embodiments of the present disclosure; and

FIG. 8 illustrates an example non-uniform discrete envelope tracking system according to embodiments of the present disclosure.

### DETAILED DESCRIPTION

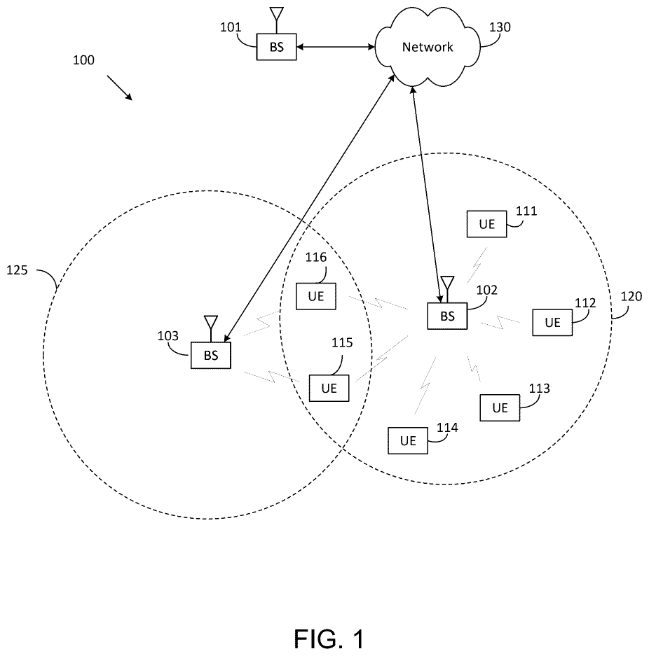

FIG. 1 through FIG. 8, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

As introduced above, power amplifiers typically consume the majority of the power budget of the base station. Moreover, their power-added efficiency (PAE), the main performance metric of a power amplifier, is often as low as 20%. The lower PAE is indicative of wasted power that contributes significantly to thermal concerns and increases the operational expenditure costs of a system. Additionally, the PAE tends to be lower for higher RF frequencies, further exacerbating the challenge for 6G design where Frequency Range 3 upper mid-band is being considered.

Digital envelope tracking (DET) improves the PAE of a power amplifier by reducing the bias voltage whenever possible. When designing a DET system, the baseline solution is to choose between discrete voltage levels that linearly span some range of minimum operating voltages for the power amplifier and some maximum voltages. In multicarrier waveforms with a high peak-to-average power ratio (PAPR), this may lead to suboptimal DET levels, reducing the PAE improvement achievable from the DET system. The primary problem is poor selection DET levels, leading to poor improvement in PAE when deploying DET. There is also a problem in computing the DET levels according to the statistics of a given waveform.

Accordingly, the present disclosure provides systems and methods for non-uniform discrete envelope tracking. As described herein, the present disclosure includes systems and methods that use non-uniform voltage levels for DET. In particular, the present disclosure provides for arbitrarily setting the voltage levels in the DET system without uniformly spacing the voltage levels, determining the non-uniformly spaced voltage levels for a power amplifier based on the one or more baseband signals, and applying the determined non-uniformly spaced voltage levels to the power amplifier to improve power efficiency. These non-uniform levels can be optimized according to a certain waveform to provide the most improvement in PAE.

To meet the demand for wireless data traffic having increased since deployment of 4G communication systems and to enable various vertical applications, 5G/NR communication systems have been developed and are currently being deployed. The 5G/NR communication system is considered to be implemented in higher frequency (mmWave) bands, e.g., 28 GHz or 60 GHz bands, so as to accomplish higher data rates or in lower frequency bands, such as 6 GHz, to enable robust coverage and mobility support. To decrease propagation loss of the radio waves and increase the transmission distance, the beamforming, massive multiple-input multiple-output (MIMO), full dimensional MIMO (FD-MIMO), array antenna, an analog beam forming, large scale antenna techniques are discussed in 5G/NR communication systems.

In addition, in 5G/NR communication systems, development for system network improvement is under way based on advanced small cells, cloud radio access networks (RANs), ultra-dense networks, device-to-device (D2D) communication, wireless backhaul, moving network, cooperative communication, coordinated multi-points (CoMP), reception-end interference cancelation and the like.

The discussion of 5G systems and frequency bands associated therewith is for reference as certain embodiments of the present disclosure may be implemented in 5G systems. However, the present disclosure is not limited to 5G systems or the frequency bands associated therewith, and embodiments of the present disclosure may be utilized in connection with any frequency band. For example, aspects of the present disclosure may also be applied to deployment of 5G communication systems, 6G or even later releases which may use terahertz (THz) bands.

FIGS. 1-3 below describe various embodiments implemented in wireless communications systems and with the use of orthogonal frequency division multiplexing (OFDM) or orthogonal frequency division multiple access (OFDMA) communication techniques. The descriptions of FIGS. 1-3 are not meant to imply physical or architectural limitations to the manner in which different embodiments may be implemented. Different embodiments of the present disclosure may be implemented in any suitably arranged communications system.

FIG. 1 illustrates an example wireless network according to embodiments of the present disclosure. The embodiment of the wireless network shown in FIG. 1 is for illustration only. Other embodiments of the wireless network 100 could be used without departing from the scope of this disclosure.

As shown in FIG. 1, the wireless network includes a gNB 101 (e.g., base station, BS), a gNB 102, and a gNB 103. The gNB 101 communicates with the gNB 102 and the gNB 103. The gNB 101 also communicates with at least one network 130, such as the Internet, a proprietary Internet Protocol (IP) network, or other data network.

The gNB 102 provides wireless broadband access to the network 130 for a first plurality of user equipments (UEs) within a coverage area 120 of the gNB 102. The first plurality of UEs includes a UE 111, which may be located in a small business; a UE 112, which may be located in an enterprise; a UE 113, which may be a WiFi hotspot; a UE 114, which may be located in a first residence; a UE 115, which may be located in a second residence; and a UE 116, which may be a mobile device, such as a cell phone, a wireless laptop, a wireless PDA, or the like. The gNB 103 provides wireless broadband access to the network 130 for a second plurality of UEs within a coverage area 125 of the gNB 103. The second plurality of UEs includes the UE 115 and the UE 116. In some embodiments, one or more of the gNBs 101-103 may communicate with each other and with the UEs 111-116 using 5G/NR, long term evolution (LTE), long term evolution-advanced (LTE-A), WiMAX, WiFi, or other wireless communication techniques.

Depending on the network type, the term “base station” or “BS” can refer to any component (or collection of components) configured to provide wireless access to a network, such as transmit point (TP), transmit-receive point (TRP), an enhanced base station (eNodeB or eNB), a 5G/NR base station (gNB), a macrocell, a femtocell, a WiFi access point (AP), or other wirelessly enabled devices. Base stations may provide wireless access in accordance with one or more wireless communication protocols, e.g., 5G/NR 3^{rd} generation partnership project (3GPP) NR, long term evolution (LTE), LTE advanced (LTE-A), high speed packet access (HSPA), Wi-Fi 802.11a/b/g/n/ac, etc. For the sake of convenience, the terms “BS” and “TRP” are used interchangeably in this patent document to refer to network infrastructure components that provide wireless access to remote terminals. Also, depending on the network type, the term “user equipment” or “UE” can refer to any component such as “mobile station,” “subscriber station,” “remote terminal,” “wireless terminal,” “receive point,” or “user device.” For the sake of convenience, the terms “user equipment” and “UE” are used in this patent document to refer to remote wireless equipment that wirelessly accesses a BS, whether the UE is a mobile device (such as a mobile telephone or smartphone) or is normally considered a stationary device (such as a desktop computer or vending machine).

Dotted lines show the approximate extents of the coverage areas 120 and 125, which are shown as approximately circular for the purposes of illustration and explanation only. It should be clearly understood that the coverage areas associated with gNBs, such as the coverage areas 120 and 125, may have other shapes, including irregular shapes, depending upon the configuration of the gNBs and variations in the radio environment associated with natural and man-made obstructions.

Although FIG. 1 illustrates one example of a wireless network, various changes may be made to FIG. 1. For example, the wireless network could include any number of gNBs and any number of UEs in any suitable arrangement. Also, the gNB 101 could communicate directly with any number of UEs and provide those UEs with wireless broadband access to the network 130. Similarly, each gNB 102-103 could communicate directly with the network 130 and provide UEs with direct wireless broadband access to the network 130. Further, the gNBs 101, 102, and/or 103 could provide access to other or additional external networks, such as external telephone networks or other types of data networks.

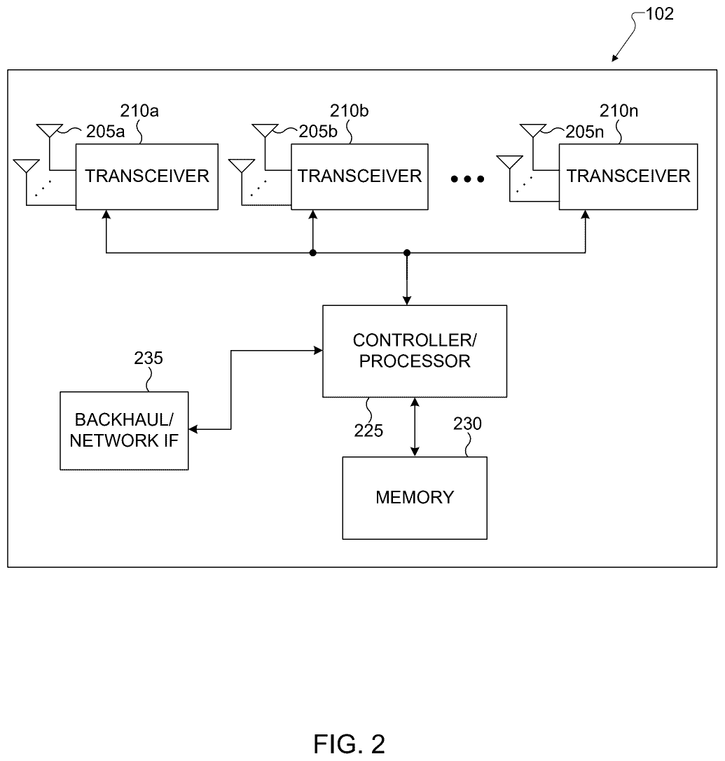

FIG. 2 illustrates an example gNB 102 according to embodiments of the present disclosure. The embodiment of the gNB 102 illustrated in FIG. 2 is for illustration only, and the gNBs 101 and 103 of FIG. 1 could have the same or similar configuration. However, gNBs come in a wide variety of configurations, and FIG. 2 does not limit the scope of this disclosure to any particular implementation of a gNB.

As shown in FIG. 2, the gNB 102 includes multiple antennas 205a-205n, multiple transceivers 210a-210n, a controller/processor 225, a memory 230, and a backhaul or network interface 235.

The transceivers 210a-210n receive, from the antennas 205a-205n, incoming RF signals, such as signals transmitted by UEs in the network 100. The transceivers 210a-210n down-convert the incoming RF signals to generate IF or baseband signals. The IF or baseband signals are processed by receive (RX) processing circuitry in the transceivers 210a-210n and/or controller/processor 225, which generates processed baseband signals by filtering, decoding, and/or digitizing the baseband or IF signals. The controller/processor 225 may further process the baseband signals.

Transmit (TX) processing circuitry in the transceivers 210a-210n and/or controller/processor 225 receives analog or digital data (such as voice data, web data, e-mail, or interactive video game data) from the controller/processor 225. The TX processing circuitry encodes, multiplexes, and/or digitizes the outgoing baseband data to generate processed baseband or IF signals. The transceivers 210a-210n up-converts the baseband or IF signals to RF signals that are transmitted via the antennas 205a-205n.

The controller/processor 225 can include one or more processors or other processing devices that control the overall operation of the gNB 102. For example, the controller/processor 225 could control the reception of UL channel signals and the transmission of DL channel signals by the transceivers 210a-210n in accordance with well-known principles. The controller/processor 225 could support additional functions as well, such as more advanced wireless communication functions. For instance, the controller/processor 225 could support beam forming or directional routing operations in which outgoing/incoming signals from/to multiple antennas 205a-205n are weighted differently to effectively steer the outgoing signals in a desired direction. Any of a wide variety of other functions could be supported in the gNB 102 by the controller/processor 225.

The controller/processor 225 is also capable of executing programs and other processes resident in the memory 230, such as an OS. The controller/processor 225 can move data into or out of the memory 230 as required by an executing process.

The controller/processor 225 is also coupled to the backhaul or network interface 235. The backhaul or network interface 235 allows the gNB 102 to communicate with other devices or systems over a backhaul connection or over a network. The interface 235 could support communications over any suitable wired or wireless connection(s). For example, when the gNB 102 is implemented as part of a cellular communication system (such as one supporting 5G/NR, LTE, or LTE-A), the interface 235 could allow the gNB 102 to communicate with other gNBs over a wired or wireless backhaul connection. When the gNB 102 is implemented as an access point, the interface 235 could allow the gNB 102 to communicate over a wired or wireless local area network or over a wired or wireless connection to a larger network (such as the Internet). The interface 235 includes any suitable structure supporting communications over a wired or wireless connection, such as an Ethernet or transceiver.

The memory 230 is coupled to the controller/processor 225. Part of the memory 230 could include a RAM, and another part of the memory 230 could include a Flash memory or other ROM.

Although FIG. 2 illustrates one example of gNB 102, various changes may be made to FIG. 2. For example, the gNB 102 could include any number of each component shown in FIG. 2. Also, various components in FIG. 2 could be combined, further subdivided, or omitted and additional components could be added according to particular needs.

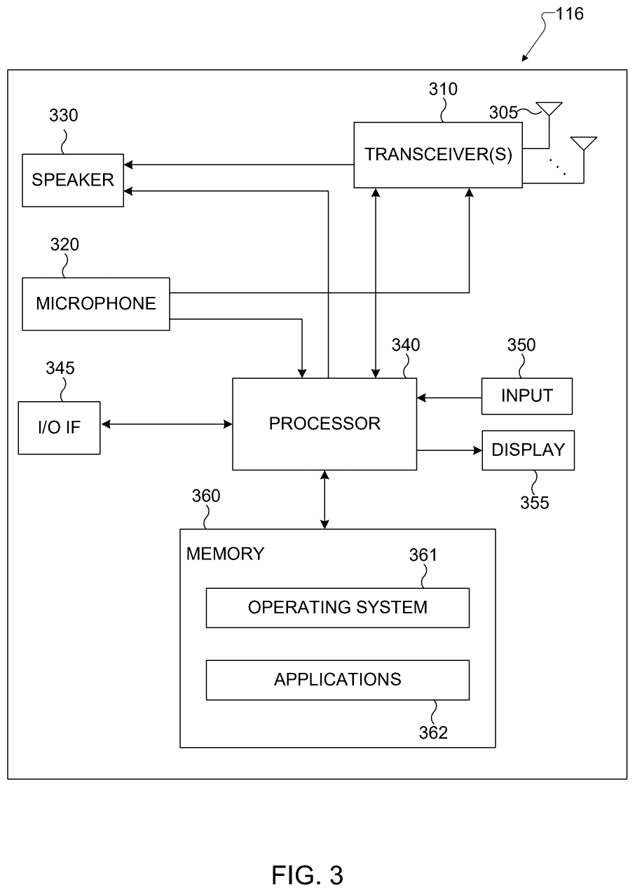

FIG. 3 illustrates an example UE 116 according to embodiments of the present disclosure. The embodiment of the UE 116 illustrated in FIG. 3 is for illustration only, and the UEs 111-115 of FIG. 1 could have the same or similar configuration. However, UEs come in a wide variety of configurations, and FIG. 3 does not limit the scope of this disclosure to any particular implementation of a UE.

As shown in FIG. 3, the UE 116 includes antenna(s) 305, a transceiver(s) 310, and a microphone 320. The UE 116 also includes a speaker 330, a processor 340, an input/output (I/O) interface (IF) 345, an input 350, a display 355, and a memory 360. The memory 360 includes an operating system (OS) 361 and one or more applications 362.

The transceiver(s) 310 receives, from the antenna 305, an incoming RF signal transmitted by a gNB of the network 100. The transceiver(s) 310 down-converts the incoming RF signal to generate an intermediate frequency (IF) or baseband signal. The IF or baseband signal is processed by RX processing circuitry in the transceiver(s) 310 and/or processor 340, which generates a processed baseband signal by filtering, decoding, and/or digitizing the baseband or IF signal. The RX processing circuitry sends the processed baseband signal to the speaker 330 (such as for voice data) or is processed by the processor 340 (such as for web browsing data).

TX processing circuitry in the transceiver(s) 310 and/or processor 340 receives analog or digital voice data from the microphone 320 or other outgoing baseband data (such as web data, e-mail, or interactive video game data) from the processor 340. The TX processing circuitry encodes, multiplexes, and/or digitizes the outgoing baseband data to generate a processed baseband or IF signal. The transceiver(s) 310 up-converts the baseband or IF signal to an RF signal that is transmitted via the antenna(s) 305.

The processor 340 can include one or more processors or other processing devices and execute the OS 361 stored in the memory 360 in order to control the overall operation of the UE 116. For example, the processor 340 could control the reception of DL channel signals and the transmission of UL channel signals by the transceiver(s) 310 in accordance with well-known principles. In some embodiments, the processor 340 includes at least one microprocessor or microcontroller.

The processor 340 is also capable of executing other processes and programs resident in the memory 360. The processor 340 can move data into or out of the memory 360 as required by an executing process. In some embodiments, the processor 340 is configured to execute the applications 362 based on the OS 361 or in response to signals received from gNBs or an operator. The processor 340 is also coupled to the I/O interface 345, which provides the UE 116 with the ability to connect to other devices, such as laptop computers and handheld computers. The I/O interface 345 is the communication path between these accessories and the processor 340.

The processor 340 is also coupled to the input 350, which includes for example, a touchscreen, keypad, etc., and the display 355. The operator of the UE 116 can use the input 350 to enter data into the UE 116. The display 355 may be a liquid crystal display, light emitting diode display, or other display capable of rendering text and/or at least limited graphics, such as from web sites.

The memory 360 is coupled to the processor 340. Part of the memory 360 could include a random-access memory (RAM), and another part of the memory 360 could include a Flash memory or other read-only memory (ROM).

Although FIG. 3 illustrates one example of UE 116, various changes may be made to FIG. 3. For example, various components in FIG. 3 could be combined, further subdivided, or omitted and additional components could be added according to particular needs. As a particular example, the processor 340 could be divided into multiple processors, such as one or more central processing units (CPUs) and one or more graphics processing units (GPUs). In another example, the transceiver(s) 310 may include any number of transceivers and signal processing chains and may be connected to any number of antennas. Also, while FIG. 3 illustrates the UE 116 configured as a mobile telephone or smartphone, UEs could be configured to operate as other types of mobile or stationary devices.

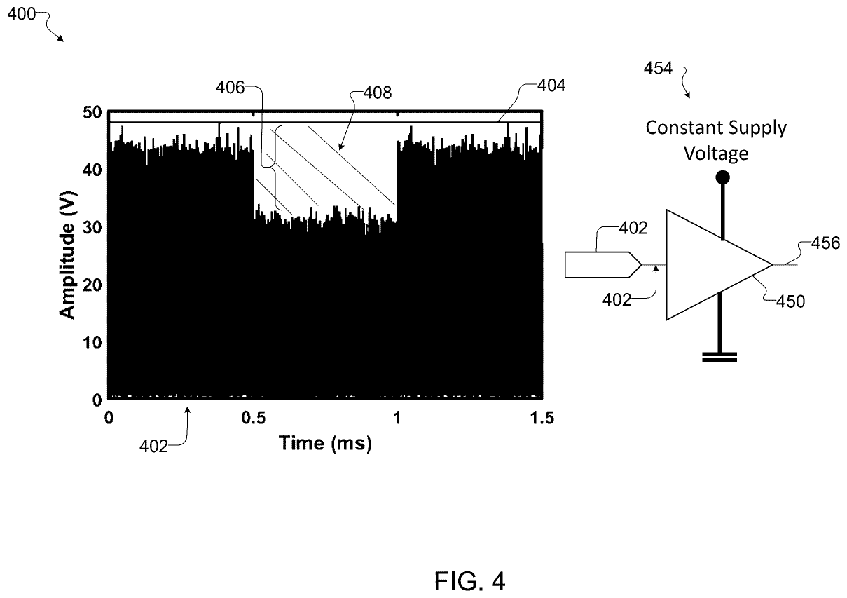

The TX processing circuitry of the gNB 101 may also include one or more power amplifiers coupled to one or more digital-to-analog converters and configured to amplify the baseband signal prior to transmission using the antenna. The one or more power amplifiers receive a supply voltage sufficient to cover the signal envelope of the baseband signal, as shown in FIG. 4.

FIG. 4 illustrates an example signal envelope 400 of a power amplifier 450. As shown in FIG. 4, the signal envelope 400, which may be represented as amplitude voltage over time, includes a RF envelope 402 representative of a baseband signal supplied to the power amplifier 450 from the DAC 452. In response to receiving the RF envelope 402, the power amplifier 450, using a constant supply voltage source 454 provides a PA supply voltage 404 to generate an output signal 456. The PA supply voltage 404 may need to have a voltage level (e.g., 48 volts as shown) greater than the RF envelope 402 to be effective. The RF envelope 402, however, fluctuates over time, creating a gap 406 between the RF envelope 402 and the PA supply voltage 404. The gap 406 creates an area of wasted energy 408 as the PA supply voltage 404 remains constant despite the RF envelope 402 changing voltage levels over time.

Further, the gap 406 forces the power amplifier 450 to operate in a power backoff mode. In a power backoff mode, the power amplifier 450 operates at a reduced power level below its maximum output, especially when dealing with signals that have large peaks in power, ensuring the power amplifier 450 stays within its linear operating region even during high signal bursts from the DAC 452. While operating in backoff mode can improve signal quality, it usually comes at the cost of reduced power efficiency as the power amplifier 450 is not operating at its peak power output. In particular, when the power amplifier 450 operates in a power backoff mode, its power added efficiency (PAE) typically decreases significantly, reducing the effectiveness of the power amplifier 450 in amplifying the RF envelope 402.

Although FIG. 4 illustrates one example of a signal envelope of a power amplifier, various changes may be made to FIG. 4. For example, the baseband signal may fluctuate between more than two voltage levels, such as between three or more voltage levels, such as between 4 or more voltage levels.

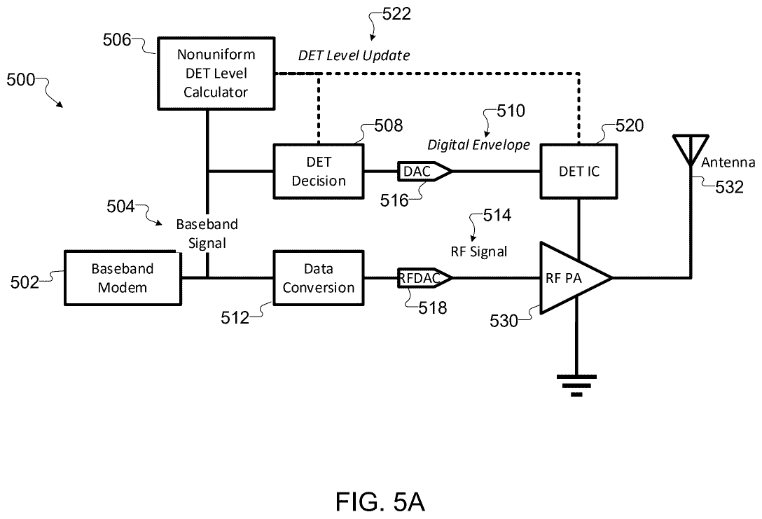

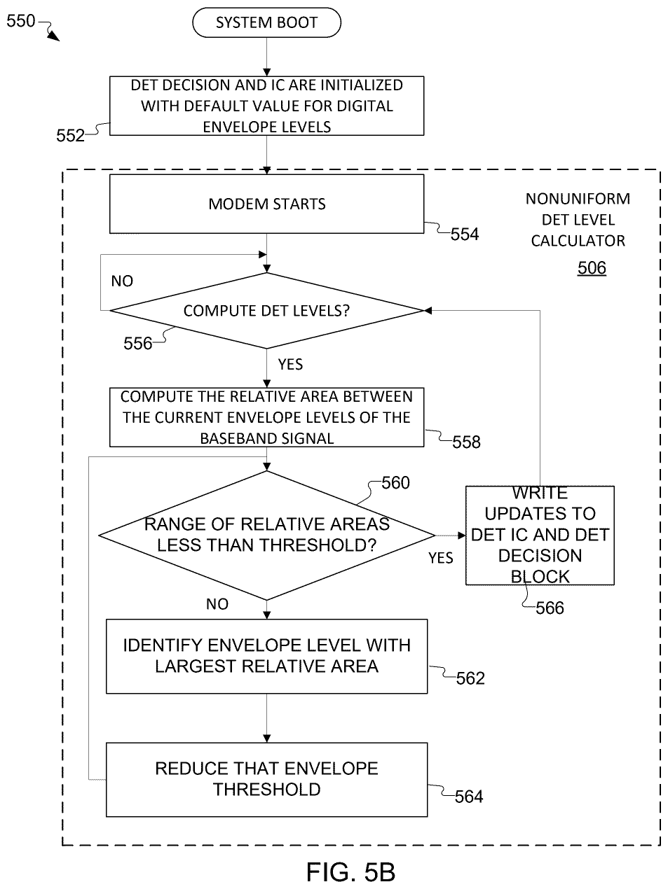

To improve power efficiency, the area of wasted energy 408 should be minimized between the RF envelope 402 and the PA supply voltage 404. This may be accomplished by configuring the power amplifier 450 to apply non-uniform voltage levels that track or change with the RF envelope 402, for example, in a non-uniform discrete envelope tracking system as shown in FIGS. 5A-5B.

FIG. 5A illustrates an example non-uniform discrete envelope tracking (DET) system 500 according to embodiments of the present disclosure. For ease of explanation, the non-uniform DET system 500 will be described as including one or more components of the wireless network 100 of FIG. 1, such as the gNB 102; however, the non-uniform DET system 500 could be implemented using any other suitable device or system. The embodiment of the non-uniform DET system 500 shown in FIG. 5 is for illustration only. Other embodiments of the non-uniform DET system 500 could be used without departing from the scope of this disclosure.

As shown in FIG. 5A, the non-uniform DET system 500 includes a baseband modem 502 configured to transmit a baseband signal 504 to a non-uniform DET level calculator 506 and a DET decision module 508. The baseband signal 504 may go through a data conversion process, including digital upconversion and filtering. The DET decision module 508 is configured to generate a digital envelope 510. The baseband modem 502 may also transmit the baseband signal 504 to a data conversion module 512 which is configured to generate a RF signal 514 based on the baseband signal 504. The data conversion module 512 may generate the digital envelope 510 by passing a signal through a DAC 516 and to a DET circuit 520. The DET circuit 520 may also receive a DET level update signal 522 from the non-uniform DET level calculator 506. The digital envelope 510 and the RF signal 514 are then input into a power amplifier 530 which amplifies the RF signal 514 using one or more DET levels received from the DET circuit 520 then transmits the amplified RF signal 514 to an antenna 532.

FIG. 5B illustrates an example flow chart of a non-uniform DET level algorithm 550 executed by a non-uniform DET level calculator 506 of the non-uniform DET system 500 of FIG. 5A according to embodiments of the present disclosure.

Let x be a complex baseband signal indexed by k. Let ƒ represent the DET decision function used by the non-uniform DET level calculator 506 that maps the kth baseband sample of x to an ET level i∈{1, 2, . . . , N} for a set of N voltages denoted by v. This DET decision must consider realistic constraints such as the minimum retention time, T. With such as constraint, the DET decision effectively operates in two steps. Firstly, the non-uniform DET level calculator 506 determines the maximum value over each window in the DET retention time. This is given as

$$y [ k ] = {max}_{i ∈ \{ m T , mT + 1 , … ( m + 1 ) T - 1 \}} x [ i ] ,$$

where

$$m = ⌊ \frac{k}{T} ⌋ .$$

Then, the DET decision can be made as

$$f ( y [ k ] ) = arg min \{ {v}_{i} ∈ v \vert {v}_{i} > y [ k ] \} .$$

The non-uniform DET level algorithm 550 is iterative, and the DET levels will be tuned over iterations indexed by t. For example, let

$${v}_{i}^{( t )}$$

represent the ith of N possible DET voltages during iteration t, and let v^{(t)}∈ [symbol] be the vector of all DET levels at this iteration. Then, let the set of samples that use the ith DET level be represented as

$${V}_{i}^{( t )} = \{ k : f ( x [ k ] ) = i \} .$$

As shown in FIG. 5B, after the non-uniform DET system 500 boots, the non-uniform DET level calculator 506 initializes with some default values for the DET levels, v (0) in operation 552. After the modem starts in operation 554 and begins transmitting the baseband signal 504 to the non-uniform DET level calculator 506, the non-uniform DET level calculator 506 determines whether to compute DET levels in operation 556. Once the non-uniform DET level calculator 506 determines that DET levels are to be computed, the non-uniform DET level calculator 506 computes the relative area between the current v^{(t)} and the baseband samples x in operation 558. The areas with respect to the ith envelope level are given as,

$${a}_{i}^{( t )} = {v}_{i}^{( t )} n ( {V}_{i}^{( t )} ) - {\int }_{k ∈ {V}_{i}^{( t )}} {\vert x [ k ] \vert}^{2} d k .$$

Here, the integral can be computed through any standard numerical method, such as the trapezoid method. Here,

$$n ( {V}_{i}^{( t )} )$$

represents the cardinality of the set of samples using the ith level. The non-uniform DET level calculator 506 then determines if the range of relative areas is less than a predetermined threshold in operation 560. If the range of relative areas is not less than the predetermined threshold, the level with the max area is identified in operation 562. For example, the level with the max area during iteration t may be given as

$$j = arg max ( {a}_{i}^{( t )} ) .$$

The non-uniform DET level calculator 506 then updates that level by reducing the envelope threshold in operation 564, hence reducing the relative area,

$${v}_{j}^{( t + 1 )} = {v}_{j}^{( t )} - β .$$

Here, β is the update which is computed based on the number of iterations and a learning rate. Let

$${v}_{i = j}^{( t + 1 )} = {v}_{i}^{( t )} , ∀ i \neq j .$$

The non-uniform DET level calculator 506 then repeats the non-uniform DET level algorithm 550 by returning to operation 558 to first recomputing the DET decisions,

$${V}_{i}^{( t + 1 )} = \{ k : f ( x [ k ] ) = i \} ,$$

using the updated weights v^{(t+1)} followed by recomputing the areas between the DET levels (operation 560) and the baseband envelope, and finally, the new DET level with the maximum area.

The non-uniform DET level calculator 506 runs the non-uniform DET level algorithm 550 until the level with the maximum area and the predetermined threshold have converged, which is determined when max(aᵢ)−min(aᵢ)<ϵ. Once converged, the DET levels v are written to the DET IC and the DET decision function, ƒ in operation 566. The non-uniform DET level calculator 506 continues to operate with the existing DET levels for an operation period. The operation period may be indefinite, based on an elapsed amount of time, or other criteria.

Alternatively, the DET levels may not be truly nonuniform. Instead, the non-uniform DET level calculator 506 may arbitrarily select the maximum and minimum voltages, according to a similar optimization-like process outlined above. The DET decision module 508 would include DET levels that are then uniformly spaced within that maximum and minimum voltages.

In another embodiment, the non-uniform DET level calculator 506 may compute the DET levels through other means. For example, the non-uniform DET level calculator 506 may use envelope statistics, such as the cumulative density function, to calculate the DET levels. Similarly, the non-uniform DET level calculator 506 may determine the DET levels through other direct manners.

Although FIGS. 5A-5B illustrate one example of a non-uniform discrete envelope tracking system, various changes may be made to FIGS. 5A-5B. For example, alternative RF hardware such, as DACs followed by upconverters and mixers, are used rather than the RFDAC. Alternatively, the DET signal may be replaced by other signals, such as a general-purpose input/output (GPIO) or other digital bus, to interface with a DET PCB or IC directly, rather than using the DAC.

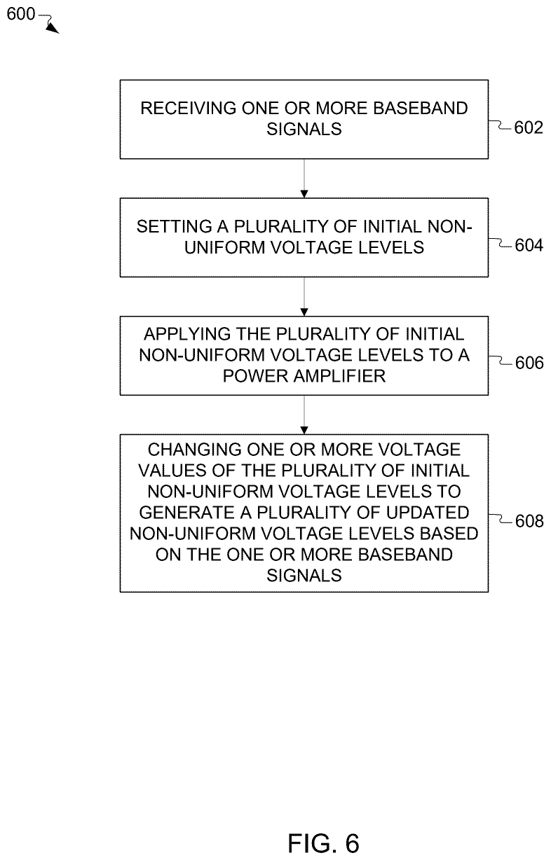

FIG. 6 illustrates an example non-uniform discrete envelope tracking method 600 according to embodiments of the present disclosure. An embodiment of the method illustrated in FIG. 6 is for illustration only. One or more of the components illustrated in FIG. 6 may be implemented in specialized circuitry configured to perform the noted functions or one or more of the components may be implemented by one or more processors executing instructions to perform the noted functions. Other embodiments of non-uniform discrete envelope tracking could be used without departing from the scope of this disclosure.

As illustrated in FIG. 6, one or more baseband signals are received at step 602. For example, a transceiver 210 of the gNB 102 may receive one or more baseband signals and transmit them to the baseband modem 502 of the non-uniform DET system 500. The baseband modem 502 may then transmit the baseband signal 504 to the non-uniform DET level calculator 506, DET decision module 508, and data conversion module 512 accordingly.

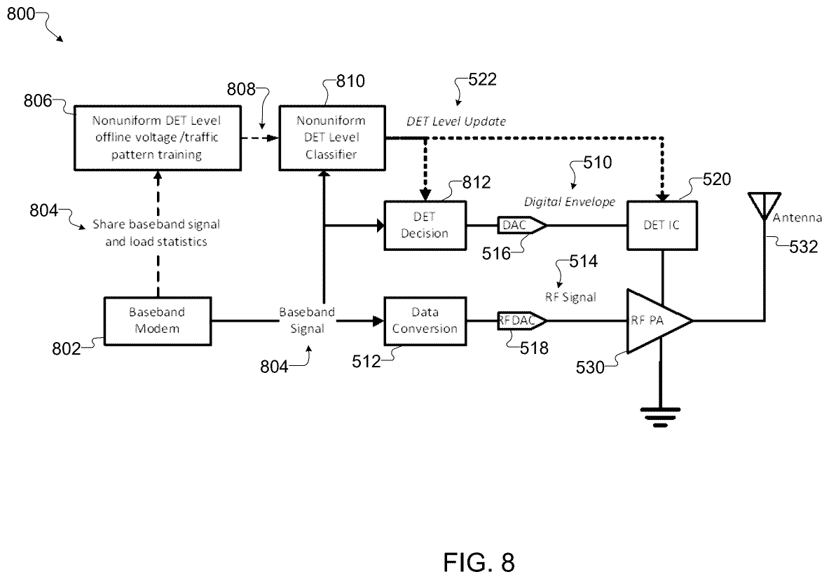

A plurality of initial non-uniform voltage levels is set at step 604. For example, the non-uniform DET level calculator 506 may set the plurality of initial non-uniform voltage levels. Each of the voltage levels in the plurality of non-uniform voltage levels is non-uniformly spaced from other voltage levels in the plurality of non-uniform voltage levels. Additionally, the plurality of initial non-uniform voltage levels may be precomputed voltage levels selected by a classifier (FIG. 8) based on a load classification of the one or more baseband signals.

The plurality of initial non-uniform voltage levels is then applied to a power amplifier at step 606. For example, the non-uniform DET level calculator 506 may transmit the plurality of initial non-uniform voltage levels to the DET circuit 520 which then transmits them to the power amplifier 530. The power amplifier 530 may also receive the RF signal 514 from the data conversion module 512 via the RF DAC 518.

One or more voltage values of the plurality of initial non-uniform voltage levels may be changed at step 608. Changing the one or more voltage values of the plurality of initial non-uniform voltage levels generates a plurality of updated non-uniform voltage levels based on the one or more baseband signals. For example, the non-uniform DET level calculator 506 may change the one or more voltage values to increase power efficiency of the power amplifier 530. For example, the non-uniform DET level calculator 506 may determine one or more relative areas given by the voltage headroom between current envelope levels and the one or more baseband signal envelopes. Then the non-uniform DET level calculator 506 may determine whether a range of the one or more relative areas exceeds a predetermined threshold. Upon determining that the range of the one or more relative areas exceeds the predetermined threshold, the non-uniform DET level calculator 506 may identify an envelope level having a largest relative area; and reduce the envelope level. However, upon determining that the range of the one or more relative areas does not exceed the predetermined threshold, the non-uniform DET level calculator 506 may provide the envelope levels to a DET decision function to generate the plurality of updated non-uniform voltage levels. Generating the plurality of updated non-uniform voltage levels may occur periodically during operation of the power amplifier 530.

Although FIG. 6 illustrates one example non-uniform discrete envelope tracking method 600, various changes may be made to FIG. 6. For example, while shown as a series of steps, various steps in FIG. 6 could overlap, occur in parallel, occur in a different order, or occur any number of times.

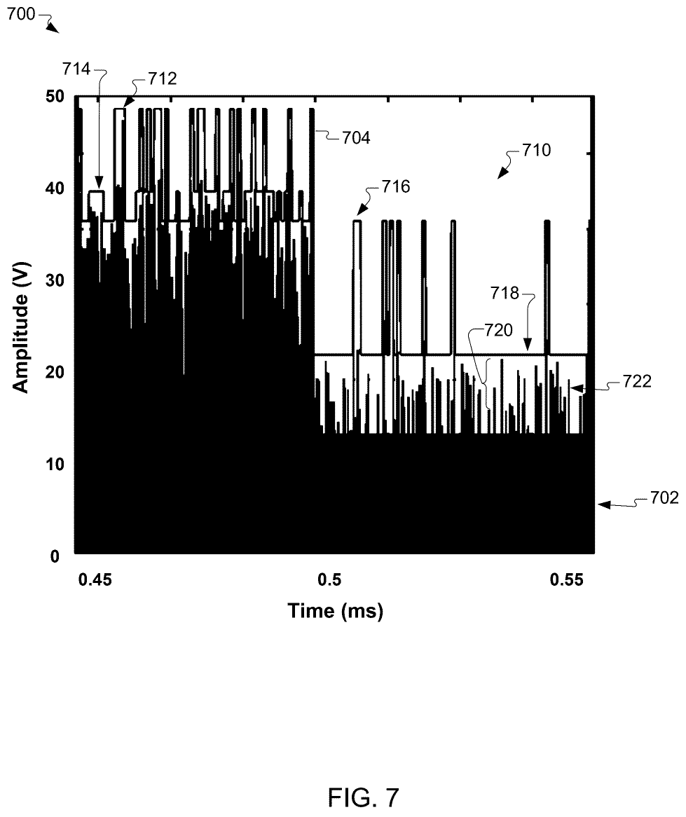

FIG. 7 illustrates an example signal envelope 700 of a non-uniform DET system 500 according to embodiments of the present disclosure. In particular, the signal envelope 700 is generated by the non-uniform DET system 500 as a result of executing the method 600 of FIG. 6. The embodiment of the signal envelope 700 shown in FIG. 7 is for illustration only. Other embodiments of the signal envelope 700 could be used without departing from the scope of this disclosure.

As shown in FIG. 7, the signal envelope 700 includes a RF envelope 702 and a PA supply voltage 704 that has a plurality of non-uniform levels 710. For example, the PA supply voltage 704 may include a first non-uniform level 712, a second non-uniform level 714, a third non-uniform level 716, and a fourth non-uniform level 718. Each of the plurality of non-uniform levels 710 of the PA supply voltage 704 are used to track the RF envelope 702 closely, such that a gap 720 between the PA supply voltage 704 and the RF envelope 702 is reduced, e.g., compared to the gap 406 of FIG. 4, subsequently reducing an area of wasted energy 722. The reduced area of wasted energy 722 leads to improved power efficiency of the power amplifier 530 during operation.

Although FIG. 7 illustrates one example of a signal envelope of a non-uniform discrete envelope tracking system, various changes may be made to FIG. 7. For example, a different quantity of voltage levels may be used, such as 2 or more voltage levels, 3 or more voltage levels, or 4 or more voltage levels.

FIG. 8 illustrates an example non-uniform discrete envelope tracking (DET) system 800 according to embodiments of the present disclosure. In particular, the non-uniform DET system 800 is configured to precompute non-uniform discrete voltage levels and classify them based on expected load scenarios. The embodiment of the non-uniform DET system 800 shown in FIG. 8 is for illustration only. Other embodiments of the non-uniform DET system 800 could be used without departing from the scope of this disclosure. The non-uniform DET system 800 is configured similarly to the non-uniform DET system 500 of FIG. 5, except as otherwise described.

As shown in FIG. 8, the DET system 800 includes a baseband modem 802 configured to transmit a baseband signal 804 to a non-uniform DET level trainer 806, a non-uniform DET level classifier 810, and a DET decision module 812. In particular, the baseband modem 802 transmits the baseband signal 804 and load statistics to the non-uniform DET level trainer 806. The non-uniform DET level trainer 806 then determines a plurality of non-uniform discrete voltage levels 808 and classifies them based on expected RF load scenarios (e.g., based on different RF traffic patterns). For example, the non-uniform DET level trainer 806 may execute the non-uniform DET level algorithm 550 (e.g., operations 556 to 566) for each expected RF load scenario and classify the non-uniform discrete voltage levels 808 accordingly.

The non-uniform DET level trainer 806 then transmits the non-uniform discrete voltage levels 808 to the non-uniform DET level classifier 810. The non-uniform DET level classifier 810 then selects a class, e.g., a subset of the non-uniform discrete voltage levels 808, based on the received baseband signal 804. For example, the non-uniform DET level classifier 810 may run in real-time by categorizing the load over a period for the baseband signal 804. Using this real-time classification of load, the non-uniform DET level classifier 810 may perform a lookup to select the most appropriate set of non-uniform discrete voltage levels 808 that were predetermined offline by the non-uniform DET level trainer 806. The non-uniform DET level classifier 810 may then use the selected non-uniform discrete voltage levels 808 as the DET level update signal 522 to update the power amplifier 530.

Although FIG. 8 illustrates one example of a non-uniform discrete envelope tracking system, various changes may be made to FIG. 8. For example, alternative RF hardware such, as DACs followed by upconverters and mixers, are used rather than the RFDAC. Alternatively, the DET signal may be replaced by other signals, such as a general-purpose input/output (GPIO) or other digital bus, to interface with a DET PCB or IC directly, rather than using the DAC.

The above flowcharts illustrate example methods that can be implemented in accordance with the principles of the present disclosure and various changes could be made to the methods illustrated in the flowcharts herein. For example, while shown as a series of steps, various steps in each figure could overlap, occur in parallel, occur in a different order, or occur multiple times. In another example, steps may be omitted or replaced by other steps.

Although the present disclosure has been described with exemplary embodiments, various changes and modifications may be suggested to one skilled in the art. It is intended that the present disclosure encompass such changes and modifications as fall within the scope of the appended claims. None of the description in this application should be read as implying that any particular element, step, or function is an essential element that must be included in the claims scope. The scope of patented subject matter is defined by the claims.

What is claimed is:

1. A method comprising:
receiving one or more baseband signals;
setting a plurality of initial non-uniform voltage levels, wherein each of the voltage levels in the plurality of non-uniform voltage levels is non-uniformly spaced from other voltage levels in the plurality of non-uniform voltage levels;
applying the plurality of initial non-uniform voltage levels to a power amplifier; and
changing one or more voltage values of the plurality of initial non-uniform voltage levels to generate a plurality of updated non-uniform voltage levels based on the one or more baseband signals.

2. The method of claim 1, wherein changing the one or more voltage values of the plurality of initial non-uniform voltage levels to generate the plurality of updated non-uniform voltage levels based on the one or more baseband signals comprises:
determining one or more relative areas given by a voltage headroom between current envelope levels and the one or more baseband signal envelopes.

3. The method of claim 2, wherein changing the one or more voltage values of the plurality of initial non-uniform voltage levels to generate the plurality of updated non-uniform voltage levels based on the one or more baseband signals further comprises:
determining whether a range of the one or more relative areas exceeds a predetermined threshold.

4. The method of claim 3, wherein changing the one or more voltage values of the plurality of initial non-uniform voltage levels to generate the plurality of updated non-uniform voltage levels based on the one or more baseband signals further comprises:
upon determining that the range of the one or more relative areas exceeds the predetermined threshold, identifying an envelope level having a largest relative area; and
reducing the envelope level.

5. The method of claim 4, wherein changing the one or more voltage values of the plurality of initial non-uniform voltage levels to generate the plurality of updated non-uniform voltage levels based on the one or more baseband signals further comprises:
upon determining that the range of the one or more relative areas does not exceed the predetermined threshold, providing the envelope levels to a DET decision function to generate the plurality of updated non-uniform voltage levels.

6. The method of claim 1, wherein the plurality of initial non-uniform voltage levels are precomputed voltage levels selected by a classifier based on a load classification of the one or more baseband signals.

7. The method of claim 1, wherein changing the one or more voltage values of the plurality of initial non-uniform voltage levels to generate the plurality of updated non-uniform voltage levels based on the one or more baseband signals occurs periodically during operation of a power amplifier.

8. An electronic device, comprising:
a transceiver; and
a processor operably coupled to the transceiver, configured to cause the electronic device to:
receive one or more baseband signals;
set a plurality of initial non-uniform voltage levels, wherein each of the voltage levels in the plurality of non-uniform voltage levels is non-uniformly spaced from other voltage levels in the plurality of non-uniform voltage levels;
apply the plurality of initial non-uniform voltage levels to a power amplifier; and
change one or more voltage values of the plurality of initial non-uniform voltage levels to generate a plurality of updated non-uniform voltage levels based on the one or more baseband signals.

9. The electronic device of claim 8, wherein the processor, when causing the electronic device to change the one or more voltage values of the plurality of initial non-uniform voltage levels to generate the plurality of updated non-uniform voltage levels based on the one or more baseband signals, is further configured to cause the electronic device to:
determine one or more relative areas given by a voltage headroom between current envelope levels and the one or more baseband signal envelopes.

10. The electronic device of claim 9, wherein the processor, when causing the electronic device to change the one or more voltage values of the plurality of initial non-uniform voltage levels to generate the plurality of updated non-uniform voltage levels based on the one or more baseband signals, is further configured to cause the device to:
determine whether a range of the one or more relative areas exceeds a predetermined threshold.

11. The electronic device of claim 10, wherein the processor, when causing the electronic device to change the one or more voltage values of the plurality of initial non-uniform voltage levels to generate the plurality of updated non-uniform voltage levels based on the one or more baseband signals, is further configured to cause the device to:
upon determining that the range of the one or more relative areas exceeds the predetermined threshold, identify an envelope level having a largest relative area; and
reduce the envelope level.

12. The electronic device of claim 11, wherein the processor, when causing the electronic device to change the one or more voltage values of the plurality of initial non-uniform voltage levels to generate the plurality of updated non-uniform voltage levels based on the one or more baseband signals, is further configured to cause the device to:
upon determining that the range of the one or more relative areas does not exceed the predetermined threshold, provide the envelope levels to a DET decision function to generate the plurality of updated non-uniform voltage levels.

13. The electronic device of claim 8, wherein the plurality of initial non-uniform voltage levels are precomputed voltage levels selected by a classifier based on a load classification of the one or more baseband signals.

14. The electronic device of claim 8, wherein changing the one or more voltage values of the plurality of initial non-uniform voltage levels to generate the plurality of updated non-uniform voltage levels based on the one or more baseband signals occurs periodically during operation of a power amplifier.

15. A non-transitory computer-readable medium comprising program code, that when executed by at least one processor of an electronic device, causes the electronic device to:
receive one or more baseband signals;
set a plurality of initial non-uniform voltage levels, wherein each of the voltage levels in the plurality of non-uniform voltage levels is non-uniformly spaced from other voltage levels in the plurality of non-uniform voltage levels;
apply the plurality of initial non-uniform voltage levels to a power amplifier; and
change one or more voltage values of the plurality of initial non-uniform voltage levels to generate a plurality of updated non-uniform voltage levels based on the one or more baseband signals.

16. The non-transitory computer-readable medium of claim 15, wherein the program code, that when executed by the at least one processor, causes the electronic device to change the one or more voltage values of the plurality of initial non-uniform voltage levels to generate the plurality of updated non-uniform voltage levels based on the one or more baseband signals, further comprises program code, that when executed by the at least one processor, causes the electronic device to:
determine one or more relative areas given by a voltage headroom between current envelope levels and the one or more baseband signal envelopes.

17. The non-transitory computer-readable medium of claim 16, wherein the program code, that when executed by the at least one processor, causes the electronic device to change the one or more voltage values of the plurality of initial non-uniform voltage levels to generate the plurality of updated non-uniform voltage levels based on the one or more baseband signals, further comprises program code, that when executed by the at least one processor, causes the electronic device to:
determine whether a range of the one or more relative areas exceeds a predetermined threshold.

18. The non-transitory computer-readable medium of claim 17, wherein the program code, that when executed by the at least one processor, causes the electronic device to change the one or more voltage values of the plurality of initial non-uniform voltage levels to generate the plurality of updated non-uniform voltage levels based on the one or more baseband signals, further comprises program code, that when executed by the at least one processor, causes the electronic device to:
upon determining that the range of the one or more relative areas exceeds the predetermined threshold, identify an envelope level having a largest relative area; and
reduce the envelope level.

19. The non-transitory computer-readable medium of claim 18, wherein the program code, that when executed by the at least one processor, causes the electronic device to change the one or more voltage values of the plurality of initial non-uniform voltage levels to generate the plurality of updated non-uniform voltage levels based on the one or more baseband signals, further comprises program code, that when executed by the at least one processor, causes the electronic device to:
upon determining that the range of the one or more relative areas does not exceed the predetermined threshold, provide the envelope levels to a DET decision function to generate the plurality of updated non-uniform voltage levels.

20. The non-transitory computer-readable medium of claim 15, wherein the plurality of initial non-uniform voltage levels are precomputed voltage levels selected by a classifier based on a load classification of the one or more baseband signals.
